(19) United States
(12) Patent Application Publication
(10) Pub. No.: US 2007/0102734 A1
(43) Pub. Date: May 10, 2007

(54) Semiconductor device and method of fabricating the same

(76) Inventors: Ju-Ri Kim, Seoul (KR); Jeong-Uk Han, Suwon-si (KR); Sung-Taeg Kang, Seoul (KR); Chang-Hun Lee, Suwon-si (KR); Sung-Chul Park, Gwacheon-si (KR)

Correspondence Address: MILLS & ONELLO LLP, ELEVEN BEACON STREET, SUITE 605, BOSTON, MA, 02108, US

(21) Appl. No.: 11/499,515

(22) Filed: Aug. 4, 2006

(30) Foreign Application Priority Data
Aug. 8, 2005 (KR) 10-2005-0072356

(51) Int. Cl. H01L 29/76

(52) U.S. Cl. 257/288

(57) ABSTRACT

Disclosed is a semiconductor device and method of fabricating the same. The semiconductor device is applicable to various electronic devices such as transistors or memories with transistors. A MOS transistor of the semiconductor device includes a first region and a second region, different in impurity concentration, which are formed in a channel region between source and drain regions. The first region is higher than the second region in impurity concentration. Impurities of the first region are concentrated on a boundary region between an active region and a field isolation film. The first region prevents a punch-through effect in the channel region, while the second region prevents current from decreasing by an increase of impurity during an operation of the transistor. The first region is formed using an additional ion implantation mask, and the second region is formed using an ion implantation mask or formed along with a well.

### CROSS-REFERENCE TO RELATED APPLICATIONS

This U.S. non-provisional patent application claims priority under 35 U.S.C. § 119 of Korean Patent Application No. 2005-072356 filed on Aug. 8, 2005, the contents of which are incorporated by reference in their entirety.

### BACKGROUND

The subject matter described herein is concerned with semiconductor devices and methods of fabricating the same, and in particular relates to a MOS transistor, a semiconductor device employing the MOS transistor, and a method of fabricating the same.

Transistors, as switching devices, are classified as various types according to their structural features. Among those transistors, MOS transistors are widely used in electronic devices such as semiconductor memories, because of their simplicity in operation and merits in higher integration density.

FIG. 1 is a sectional view of a conventional MOS transistor.

Referring to FIG. 1, a MOS transistor includes a gate electrode 5 formed by interposing a gate insulation film 4 with a semiconductor substrate 1, and source and drain regions 2 and 3 formed under the surface of the substrate 1 and isolated from each other with the gate electrode 5 interposed therebetween. During operation, a channel is formed to interconnect the source and drain regions with each other under the gate electrode 5 in the substrate 1. Carriers (electrons or holes) move along the channel.

With higher integration density of semiconductor devices, the gate electrode 5 is shortened in length and, as a result, a channel length of the MOS transistor becomes shorter. In general, distribution profiles of electric field and potential in the channel region are controlled by a voltage applied to the gate electrode 5, but it is possible to make current flow through the channel region even in a non-conductive state of the gate electrode 5 as the channel length becomes smaller. That is, while a depletion region is generated in the drain region 3 in proportion to a voltage applied thereto, the reduction of channel length may cause the depletion region of the drain region 3 to be connected with the depletion region of the source region 2. In this case, even when there is no channel, as the voltage applied to the drain region 3 influences the source region 2, the punch-through effect occurs to cause current flow between the source and drain regions 2 and 3.

Whereas there is a method of injecting impurities into the channel region in order to prevent the punch-through effect, the concentration of the impurities injected thereinto is increasing the MOS transistor is made smaller. At this point, the impurities injected into the channel region are different from those in the source and drain regions 2 and 3 in conductivity, by which an operating current decreases as the impurity concentration increases in the channel region.

### SUMMARY OF THE INVENTION

The present invention provides a semiconductor device and method of fabricating the same, improving operational characteristics.

In one aspect, the present invention is directed to a semiconductor device comprising: a field isolation film defining an active region in a substrate; a gate electrode extending crossing the active region and the field isolation film; a source region and a drain region formed in the active region at both sides of the gate electrode; and a first region doped with a first impurity with a first concentration and a second region doped with the first impurity with a second concentration different from the first concentration, the first region being formed in a channel region under the gate electrode and extending in a direction parallel to a lengthwise direction of the channel region.

In one embodiment, the first concentration is higher than the second concentration and the first region includes a boundary region between the channel region and the field isolation film.

In another embodiment, the first region comprises two portions isolated from each other, and the second region is disposed between the two portions.

In another embodiment, the field isolation film adjacent to the first region includes the first impurity with the first concentration.

In another embodiment, the source region and the drain region are doped with a second impurity, the first and second impurities having different electrical conductivity types.

In another embodiment, the first impurity is at least one of B, BF2, and In.

In another embodiment, the gate electrode includes a charge storage film.

In another embodiment, the gate electrode comprises: a lower gate on a gate insulating layer; an insulation film on the lower gate; and an upper gate on the insulation film.

In another embodiment, the semiconductor device further comprises a floating diffusion region formed between the source region and the drain region. The gate electrode comprises a selection gate electrode and a memory gate electrode including the charge storage film, the selection gate electrode and the memory gate electrode being isolated from each other at both sides of the floating diffusion region.

In another embodiment, the first and second regions are formed in the channel region under the selection gate electrode.

In another embodiment, the first and second regions are formed in the channel region under the memory gate electrode.

In another embodiment, the first concentration is from about 2.0×10¹⁴ to about 2.9×10¹⁴ ions/cm³.

In another embodiment, the second concentration is from about 1.0×10¹⁴ to about 1.9×10¹⁴ ions/cm³.

In another aspect, the present invention is directed to a semiconductor device comprising: a field isolation film defining an active region in a substrate; a selection gate electrode extending crossing the active region and the field isolation film; a memory gate electrode disposed in parallel with the selection gate electrode and including a floating gate; a source region formed in the active region at a side of the memory gate electrode; a drain region formed in the active region at a side of the selection gate electrode; a floating diffusion region formed in the active region between the selection gate electrode and the memory gate electrode; a first region doped with an impurity with a first concentration and a second region doped with the impurity with a second concentration different from the first concentration, formed in a channel region under the selection gate electrode and extending in a direction parallel to a lengthwise direction of the channel region; and wherein the first concentration is higher than the second concentration and the first region includes a boundary region between the channel region and the field isolation film.

In one embodiment, the semiconductor device further comprises a gate insulating film and a tunneling insulating film between the floating gate and the substrate.

In another embodiment, the tunneling insulating film is thinner than the gate insulating film.

In another embodiment, the tunneling insulating film is disposed on the floating diffusion region.

In another aspect, the present invention is directed to a method of fabricating a semiconductor device comprising: forming a field isolation film defining an active region in a substrate; implanting an impurity into the active region and forming a first region with a first concentration and a second region with a second concentration different from the first concentration which extend along a first direction; forming a gate electrode extending along a second direction crossing the first direction and crossing the active region and the field isolation film, on the first and second regions; and forming a source region and a drain region in the active region at both sides of the gate electrode.

In one embodiment, the first concentration is higher than the second concentration and the first region includes a boundary region between the channel region and the field isolation film.

In another embodiment, the first region includes two portions isolated from each other, and the second region is disposed between the two portions.

In another embodiment, the first region is formed by implanting the impurity in a direction at an angle with respect to an imaginary line perpendicular to the first region, the angle being within a range of from about 7 to about 30 degrees.

In another embodiment, the first region is formed by implanting the impurity under a mask using a photoresist pattern that exposes an area including the boundary region.

In another embodiment, the method further comprises: implanting an impurity into the substrate to form a well, wherein the first region is formed within the well by implanting an additional impurity and the second region is formed between the two portions of the first regions.

In another embodiment, the method further comprises: implanting an impurity into the substrate for controlling a threshold voltage, wherein the first region is formed by implanting an additional impurity and the second region is formed between the two portions of the first region.

In another aspect, the present invention is directed to a method of fabricating a semiconductor device comprising: forming a field isolation film defining an active region in a substrate; forming a selection gate electrode on the active region and the field isolation film; forming a memory gate electrode on the active region, the memory gate electrode being in parallel with the selection gate electrode and including a floating gate; forming a source region in the active region at a side of the memory gate electrode; forming a drain region in the active region at a side of the selection gate electrode; forming a floating diffusion region in the active region between the selection gate electrode and the memory gate electrode; forming a first region doped with an impurity with a first concentration and a second region doped with the impurity with a second concentration different from the first concentration, formed in a channel region under the selection gate electrode and extending in a direction parallel to a lengthwise direction of the channel region; and wherein the first concentration is higher than the second concentration and the first region includes a boundary region between the channel region and the field isolation film.

In one embodiment, the method further comprises forming a gate insulating film and a tunneling insulating film between the floating gate and the active region.

In another embodiment, the tunneling insulating film is thinner than the gate insulating film.

In another embodiment, the tunneling insulating film is formed on the floating diffusion region.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a sectional view of a conventional MOS transistor.

FIG. 2 is a plane view illustrating a semiconductor device in accordance with an embodiment of the invention.

FIGS. 3A and 3B are sectional views taken along lines I-I′ and II-II′, respectively, of FIG. 2.

FIG. 4 is a plane view illustrating a semiconductor device in accordance with another embodiment of the invention.

FIGS. 5A and 5B are sectional views taken along lines III-III′ and IV-IV′, respectively, of FIG. 4.

FIG. 6 is a plane view illustrating a semiconductor device in accordance with still another embodiment of the invention.

FIGS. 7A and 7B are sectional views taken along lines V-V′ and VI-VI′, respectively, of FIG. 6.

FIGS. 8A through 12A and 8B through 12B are sectional views illustrating processing steps for fabricating the semiconductor device in accordance with an embodiment of the invention.

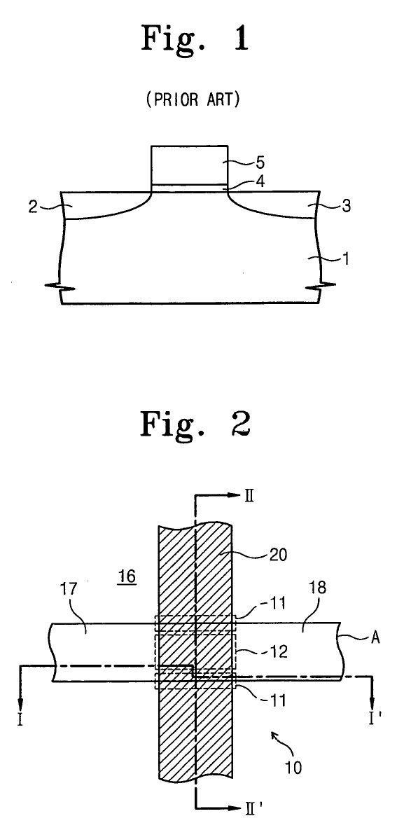

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

FIG. 2 is a plane view illustrating a semiconductor device in accordance with an embodiment of the invention.

Referring to FIG. 2, a field isolation film 16 is arranged to define an active region ‘A’ in a substrate 10. Over the active region ‘A’, a gate electrode 20 is disposed crossing the field isolation film 16. The field isolation film 16 may be formed by means of the process of shallow trench isolation (STI). In the active region ‘A’ at both sides of the gate electrode 20, a source region 17 and a drain region 18, including ionic impurities, are spaced from each other. In addition, a first region 11 and a second region 12, containing ionic impurities of first and second concentrations, respectively, are formed in the active region ‘A’ under the gate electrode 20, i.e., in the channel region. As illustrated in FIG. 2, the first region 11 includes two portions separately disposed in the active region ‘A’ adjacent to the field isolation film 16, while the second region 12 may be formed between the two portions of the first region 11. The function and effect of the differential profiles of impurity concentration between the first and second regions 11 and 12 in the channel region can be understood through the following description of a vertical structure of the transistor in accordance with the invention.

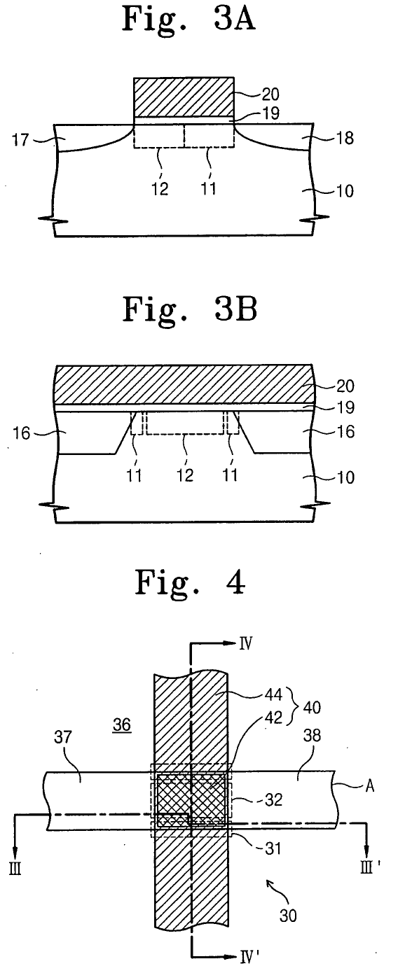

FIGS. 3A and 3B are sectional views taken along with I-I′ and II-II′, respectively, of FIG. 2.

Referring to FIG. 3A, the first and second regions 11 and 12 are disposed in the channel region between the source and drain regions 17 and 18. Between the substrate 10 and the gate electrode 20 is interposed a gate insulation film 19. The source and drain regions 17 and 18 are doped with N or P-type ionic impurities in accordance with conductivity of the transistor as the semiconductor device. The first and second regions 11 and 12 include P or N-type ionic impurities, different from the source and drain regions 17 and 18. The first and second regions 11 and 12, different from each other in impurity concentration, have different operational characteristics.

The first region 11 with high-concentration ionic impurities prevents various drawbacks that would be generated as the channel length becomes shorter. For example, the first region 11 interrupts generation of punch-through due to a short channel effect when a shrinking-down of the gate electrode 20 along high integration shortens a channel length. The first region 11 is designed to contain ionic impurities with concentration enough to prevent the punch-through effect under the condition of shortened channel length.

If the channel region entirely contains high-concentration ionic impurities, it may greatly reduce a current flowing between the source and drain regions 17 and 18. However, as the transistor of the invention employs the second region 12 that has ionic impurities lower than the first region 11 in concentration, a sufficient current can flow through the second region 12 along the channel region.

Referring to FIG. 3B, the first region 11 is formed to include a boundary region between the channel region and the field isolation film 16. The second region 12 is formed to include a center region of the channel region.

The transistor in accordance with the invention is configured such that the channel region, i.e., the portion overlapping with the gate electrode 20 in the active region ‘A’, includes the two divisional regions 11 and 12 functioning in different characteristics, but the first and second regions 11 and 12 may be variable in pattern and location in the channel region.

When the second region 12 is widely spreading covering the center region of the channel region, it is permissible for the most abundant current to flow through the channel region in the condition of minimum rate for current reduction. The first region 11 is configured to protect the transistor from punch-through by the short channel effect even when high-concentration ionic impurities are concentrated on the least area at the boundary region between the channel region and the field isolation film 16.

Regarding these points, the first regions 11 are formed in a pair of divided portions located at the boundary region between the channel region and the field isolation film 16, while the second region 12 is formed in the channel region between the pair of portions of the first region 11. Here, as shown in FIG. 3B, the first region 11 may extend toward parts of the field isolation film 16 because ionic impurities can be injected even into the field isolation film 16 during the ion implantation process.

As such, when ionic impurities are present around the boundary region between the channel region and the field isolation film 16, there are advantages relative to parasitic capacitors, as follows, as well as the function of preventing the punch-through effect.

Parasitic transistors may be generated at the boundary region between the channel region and the field isolation film 16, causing hump or inverse narrow-width effect that forces the channel length to be shorter. This is especially true when the field isolation film 16 is formed by the STI processing technique, because it generate grooves, so called ‘dents’, at top edges of the field isolation film 16. For instance, forming the field isolation film 16 with trenches in the substrate 10 utilizes a hard mask for trench formation. During this, a pad oxide film included in the hard mask may be over-etched away to generate dents on the field isolation film 16. Further, when a nitride liner is formed on the inner wall of the trench for protecting against stress, the nitride liner would be excessively etched away, while etching the hard mask of nitride, to generate dents on the field isolation film 16.

As an electric field is concentrated on the dents, threshold voltages of the parasitic transistors may become lower to cause more serious degradation such as hump shapes thereon. However, the first region 11 according to the invention, which includes high-concentration ionic impurities implanted into the boundary region between the channel region and the field isolation film 16, is helpful to raise the threshold voltages of the parasitic transistors, minimizing the hump or inverse narrow width effect.

The invention provides a feature of forming plural regions with different concentrations of ionic impurities in the channel region, which is applicable to other semiconductor devices, in addition to the MOS transistor, which use such a transistor structure. Another feature applicable to a semiconductor memory device will now be described.

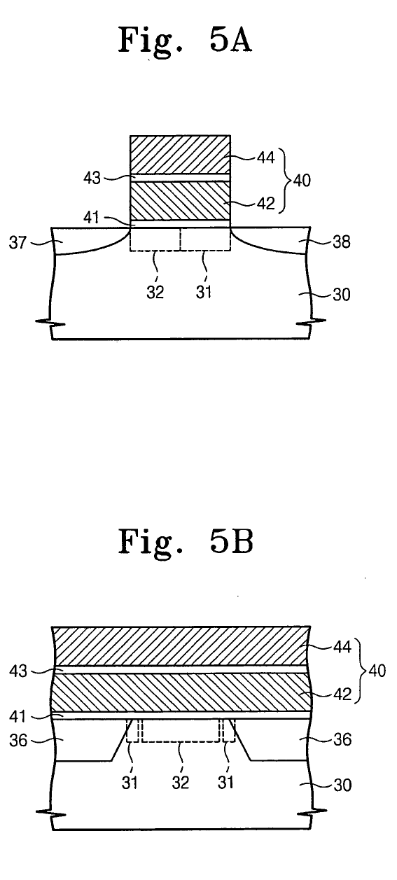

FIG. 4 is a plane view illustrating a semiconductor device in accordance with another embodiment of the invention. FIGS. 5A and 5B are sectional views taken along with III-III′ and IV-IV′, respectively, of FIG. 4.

Referring to FIG. 4, a field isolation film 36 is formed to define an active region ‘A’ in a substrate 30. A gate electrode 40 is disposed over the channel region. The gate electrode 40 includes a top electrode 44 crossing the active region ‘A’, and a charge storage film 42 located at the crossing area between the top electrode 44 and the active region ‘A’. At both sides of the gate electrode 40 are disposed a source region 37 and a drain region 38 in the active region ‘A’. In the channel region between the source and drain regions 37 and 38, a first region 31 and a second region 32 are formed. The first region 31 may be confined only in the channel region without extending to the field isolation film 36, or without being present at a boundary region between a channel region and the field isolation film 36.

Referring to FIG. 5A, the charge storage film 42 is interposed between upper and lower insulation films 43 and 41 on the substrate 30. The charge storage film 42 may hold charges, by which the memory cell is conditioned in logic ‘0’ or ‘1’ in correspondence with presence of charges therein.

The substrate 30, the lower insulation film 41, and charge storage film 42 have their inherent energy bandgaps. The differences between the energy bandgaps generate potential barriers at interfaces among them. When the gate electrode 40 is supplied with a voltage and the source and drain regions 36 and 37 are biased by an electric field, charges move along the channel region. Then, the charges partially tunnel into the charge storage film 42, then being stored therein, through the lower insulation film 41, accompanying with energy sufficient to pass the potential barrier of the lower insulation film41.

The charge storage film 42 may be made of a conductive or non-conductive insulation material. According to the property with conduction or non-conduction of the charge storage film 42, the memory device is divided into floating-gate and floating-trap types. The floating-gate memory device is comprised of a floating gate 42 of conductive polysilicon that is isolated by the insulation films 41 and 43 between the top electrode 44 and the substrate 30. The charges are stored in the floating gate 42. The floating-trap memory device employs a non-conductive insulation film 42, e.g., a nitride film, interposed between the substrate 30 and the top electrode 44. The charges are stored in traps formed in the non-conductive insulation film 42.

The lower insulation film 41 functions as a tunneling insulation film, which may be formed by means of thermal oxidation. In the floating-gate memory device, charges stored in the conductive floating gate 42 would be lost due to damage on the lower insulation film 41, so that the lower insulation film 41 may be formed in a relatively large thickness in order to maintain data retention reliability. The upper insulation film 43 functions as an inter-gate insulation film formed between the floating gate 42 and the top electrode 44, which may be formed of oxide-nitride-oxide (ONO) film. In the floating-trap memory device, the upper insulation film 43 may be formed of a silicon oxide or a dielectric material that has a large energy bandgap and a high dielectric constant.

Regardless of whether the device is of the floating-gate or floating-trap type, there would be a problem of punch-through even in a flash memory device employing such a transistor structure as a unit cell in accordance with the dimensional shrinking-down. But this punch-through effect can be prevented by the presence of the first and second regions 31 and 32 doped respectively with a different concentration of ionic impurities.

Referring to FIG. 5B, the first region 31 including two portions separated from each other are placed at edges of the channel region. Between the two portions of the first region 31 is disposed the second region 32. The first region 31 is formed being higher than the second region in concentration of ionic impurities, which prevents various problems arising from shortened channel length, e.g., punch-through. The second region 32 with low concentration prevents an operating current from being reduced when the impurity concentration of the channel region is so high.

Another feature of the invention, namely, electrically erasable and programmable read-only memory (EEPROM) cells as a nonvolatile semiconductor memory device, will now be described in detail.

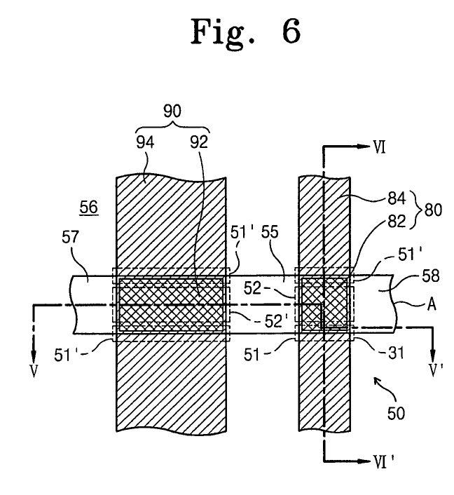

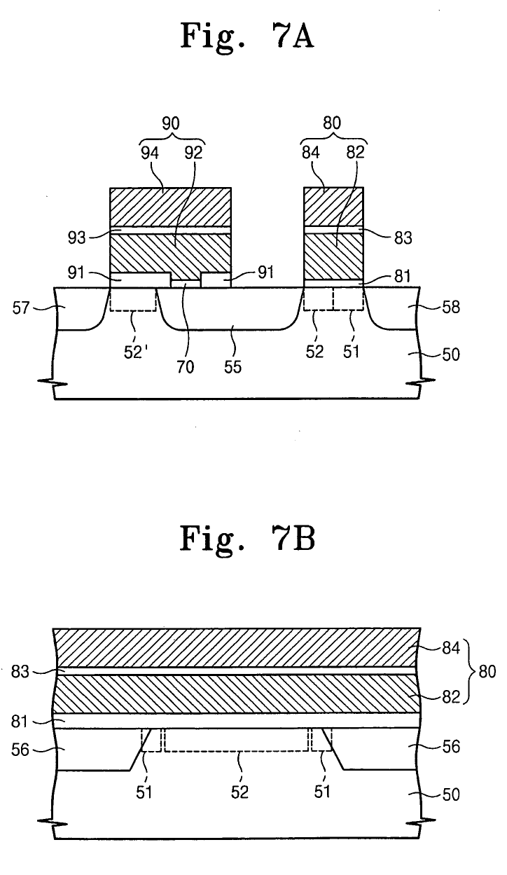

FIG. 6 is a plane view illustrating a semiconductor device in accordance with still another embodiment of the invention. FIGS. 7A and 7B are sectional views taken along lines V-V′ and VI-VI′, respectively, of FIG. 6.

Referring to FIG. 6, a field isolation film 56 is disposed to define an active region ‘A’ in a substrate 50. Over the active region ‘A’, a memory gate electrode 90 and a selection gate electrode 80 are arranged crossing the field isolation film 56.

Referring to FIG. 7A, the memory gate electrode 90 includes a floating gate 92 and a control gate 94. The floating gate 92 may store charges, by which the memory cell is conditioned in logic ‘0’ or ‘1’ in correspondence with presence of charges in the floating gate 92. A tunneling insulation film 70 is disposed at a predetermined area between the substrate 50 and the floating gate 92. Charges pass through the tunneling insulation film 70 and then are stored in the floating gate 92. Except for the predetermined area at which the tunneling insulation film 70 is formed, a gate insulation film 91 is interposed between the substrate 50 and the floating gate 92. Between the floating gate 92 and the control gate 94 is interposed an inter-gate insulation film 93. While the selection gate electrode 80 may be formed of upper and lower gates 82 and 84 in correspondence with the memory gate electrode 90 on the processing procedure thereof, there is no charge in the lower gate 82. The lower gate 82 is connected with the upper gate 84 at a predetermined location on the substrate 50. The lower gate 82 is interposed between insulation films 81 and 83.

Source and drain regions 57 and 58 are positioned at sides of the memory gate electrode 90 and the selection gate electrode 80, respectively. Between the memory gate electrode 90 and the selection gate electrode 80 is disposed a floating diffusion region 55. Two transistors are completed: one by the memory gate electrode 90 and the source region 57 and the floating diffusion region 55 at both sides of the memory gate electrode 90; and the other by the selection gate electrode 80 and the floating diffusion region 55 and the drain region 58 at both sides of the selection gate electrode 80.

While there are differences between the memory gate electrode 90 and the selection gate electrode 80 in structure and function, the two transistors are all affected from the shrinking-down of the channel region by the tendency of high integration. Thus, ionic impurities are injected into the channel region so as to prevent a punch-through effect therein, for which P-type ionic impurities are implanted into the N-type transistor in the concentration of 1.0×10^{14˜1.9×10}¹⁴ ions/cm³, recently, in more of 2.0×10¹⁴˜2.9×10¹⁴ ions/cm³ according as the transistor becomes smaller in size.

Referring to FIG. 7B, on the substrate 50 are formed the selection gate electrode 80, the lower insulation film 81, and the upper insulation film 83. Two portions of the first region 51 are formed at a boundary region between the channel region and the field isolation film 56. The first region 51 is provided to prevent the punch-through effect therein, including high-concentration ionic impurities of 2.0×10¹⁴˜2.9×10¹⁴ ions/cm³. The second region 52 is settled between the two portions of the first region 51. The second region 52 is doped with 1.0×10¹⁴˜1.9×10¹⁴ ions/cm³ that is relatively lower than the concentration of the first region 51 in order not to reduce an operating current. Such a structure with the first and second regions 51 and 52 different in impurity concentration on the channel region is available to a region including the memory gate electrode 90, as illustrated in FIGS. 6 and 7B, except for a region including the selection gate electrode 80.

Considering embodiments with several kinds of semiconductor devices, the present invention may not be restrictive thereto and rather is applicable to other semiconductor devices using the transistor described herein.

A method for fabricating the semiconductor device in accordance with the invention, e.g., the EEPROM cell, will now be described in detail. Processing steps according to the method include the procedure of forming the first and second regions, also adaptable to other semiconductor devices or transistors described above.

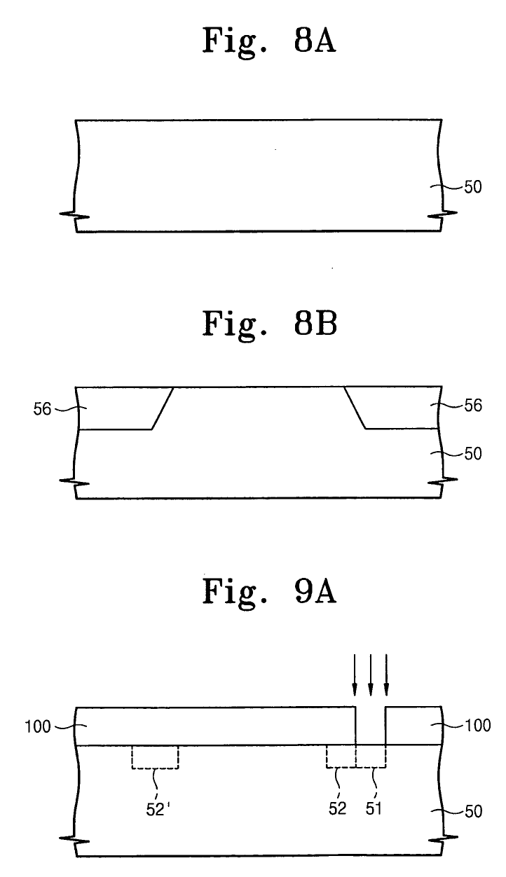

FIGS. 8A through 12A and 8B through 12B are sectional views illustrating processing steps for fabricating the semiconductor device in accordance with the embodiments of the invention, taken along lines V-V′ and VI-VI′, respectively, on the EEPROM cell shown in FIG. 6.

First, referring to FIGS. 8A and 8B, the field isolation film 56 is formed to confine the active region ‘A’ in the substrate 50. The field isolation film 50 is completed through the steps of etching away a predetermined region of the substrate 50 to form a trench, filling the trench with an insulation film such as a high-density plasma (HDP) oxide that has an excellent gap-filling quality, and then flattening the insulation film by means of a chemical-mechanical polishing (CMP) technique.

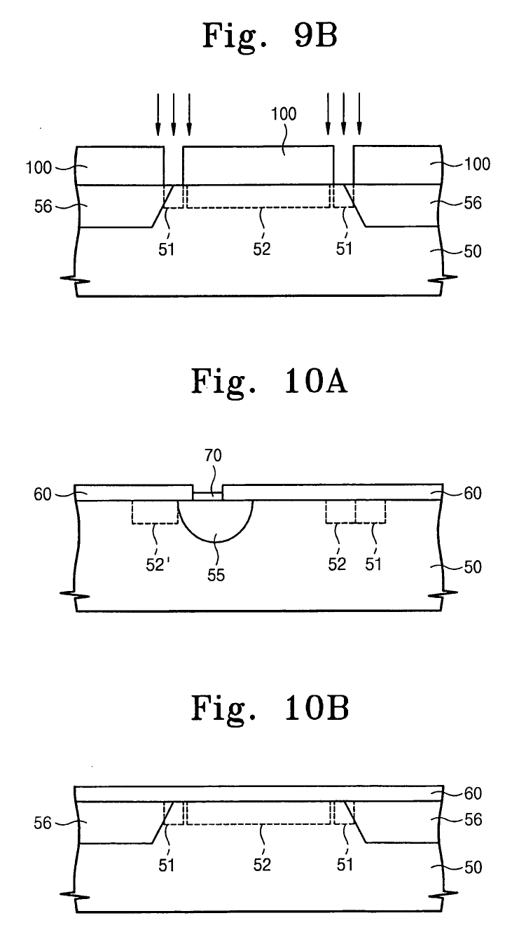

Referring to FIGS. 9A and 9B, ionic impurities are selectively implanted (or injected) into the substrate 50, forming the first and second regions 51 and 52. During this process, as shown in FIGS. 6 and 9A, it may form other first and second regions 51′ and 52′ even on the region of the memory gate electrode in the EEPROM cell.

The first region 51 may be formed by implanting ionic impurities under an ion implantation mask 100. The ion implantation mask 100 can be formed by means of a photolithography process after coating a photoresist film on the substrate 50. The ionic impurities, e.g., B, BF2, or In, or a composite of them for an N-type transistor, are injected into the disclosed regions by the ion implantation mask 100 to form the first regions 51. As an operating current would be reduced with an increase of the ionic impurity concentration, it is preferred to focus the first region 51 just on the boundary region between the active region and the field isolation film 56. For this control, the ionic impurities may be implanted thereinto at a slope of 7˜30° with respect to an imaginary line perpendicular to the first region. Then, as illustrated in FIG. 9B, this slanting ion implantation may make the first regions 51 extend to the field isolation film 56 adjacent to the active region. The second region 52 may be formed from ion implantation under an additional ion implantation mask that is prepared by a photoresist film as like the first region 51.

In addition to the aforementioned approaches, other methods of forming the first and second regions 51 and 52 may be employed. For example, first, after defining the regions where the first and second regions 51 and 52 will be formed by an ion implantation mask, ionic impurities with low concentration are implanted thereinto. After defining the regions where the first region 51 will be formed again, ionic impurities with high concentration are further implanted thereinto.

Alternatively, the second region 52 may be completed without using an additional ion implantation mask. That is, after forming the field isolation film 56 and a well (not shown) with the same impurity concentration necessary for the second region 52 in the substrate 50, ionic impurities are injected into the first region 51 under the ion implantation mask 100. Thereby, the second region 52 of low concentration is formed in the channel region of the active region except the first region 51.

Similar to the approach for the well, when ionic impurities are further implanted only into the first region 51 after injecting ionic impurities for controlling a threshold voltage entirely into the substrate 50, the second region 52 is also completed in the channel region except the first region 51. In this case, as can be seen from FIGS. 9A and 9B, there is no need of an additional step for the second region 52.

It is not required that a sequence of ion implantation steps for the first and second regions 51 and 52 be the same. For example, it is permissible to inject ionic impurities under the first ion implantation mask 100 after completing the overall ion implantation for the substrate 50.

Referring to FIGS. 10A and 10B, the floating diffusion region 55 is formed in the substrate 50, for which ionic impurities are implanted thereinto after defining the predetermined area using a photoresist pattern. These ionic impurities are different from those ionic impurities of the first and second regions 51 and 52 in conductivity. After completing the floating diffusion region 55, an insulation film 60 made of oxide is deposited on the substrate 50 and an opening is formed through the insulation film 60 at a portion overlapping with the floating diffusion region 55 by means of a photoresist pattern. In the opening, the tunneling insulation film 70 is formed to a thickness smaller than that of the insulation film 60.

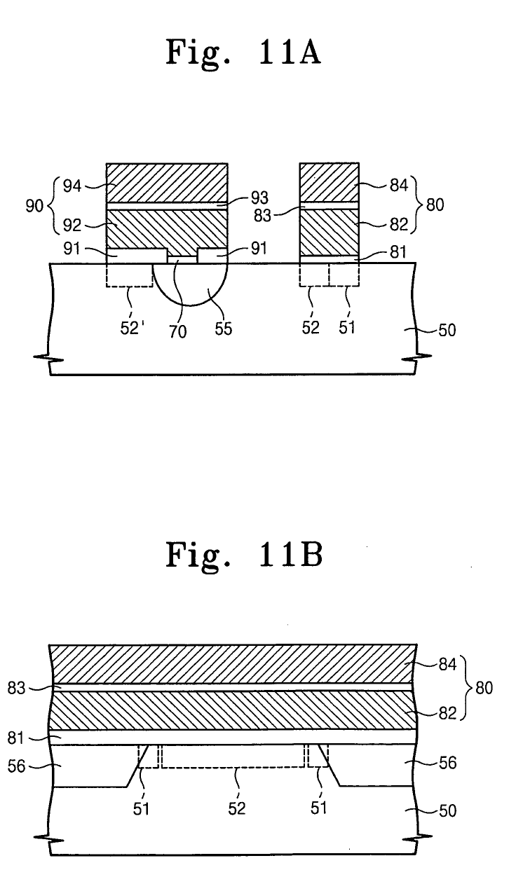

Referring to FIGS. 11A and 11B, a conductive film, an insulation film, and another conductive film are sequentially stacked and patterned on the insulation film 60. On the floating diffusion region 55 are formed the memory gate electrode 90 composed of the control and floating gates 94 and 92. The gate insulation film 91 and the inter-gate insulation film 93 are formed respectively on and under the floating gate 92. Being isolated from the memory gate electrode 90, the selection gate electrode 80 is formed to include the upper and lower gates 84 and 82. The upper and lower gates 84 and 82 are connected with each other at a predetermined position of the substrate 50. The lower and upper insulation films 81 and 83 are formed respectively on and under the lower gate 82.

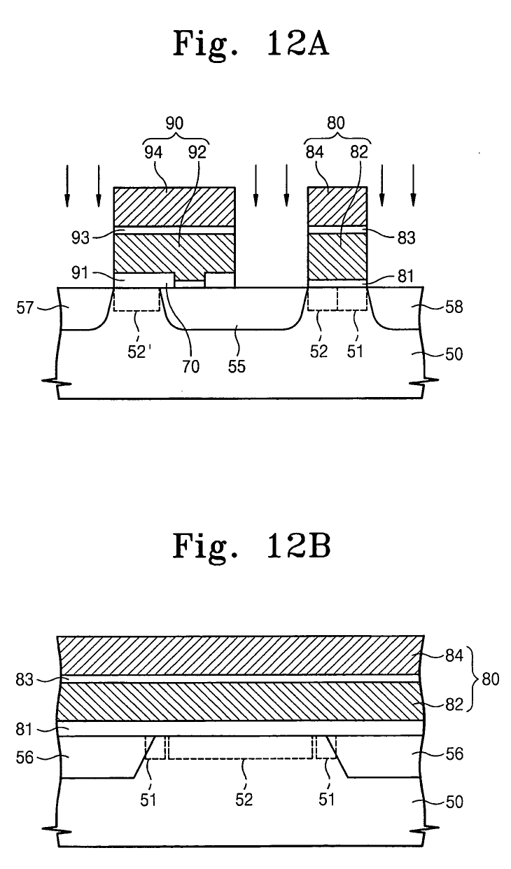

Next, referring to FIGS. 12A and 12B, ionic impurities are injected using the memory and selection gate electrodes 90 and 80 as an ion implantation mask. During this, the source region 57 is formed at a side of the memory gate electrode 90 while the drain region 58 is formed at a side of the selection gate electrode 90. The floating diffusion region 55 is formed extending between the memory and selection gate electrodes 90 and 80.

As stated above, the invention is advantageous to preventing various problems, such as the punch-through effect, which would be caused by shortened channel length due to the shrinking-down of transistors in accordance with high integration, in a MOS transistor and a semiconductor device such as a memory employing the MOS transistor.

In particular, it prevents current reduction even in the condition of injecting high-concentration ionic impurities into the channel region for preventing the punch-through.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor device comprising:
a field isolation film defining an active region in a substrate;
a gate electrode extending with crossing the active region and the field isolation film;
a source region and a drain region formed in the active region at both sides of the gate electrode; and
a first region doped with a first impurity with a first concentration and a second region doped with the first impurity with a second concentration different from the first concentration, the first region being formed in a channel region under the gate electrode and extending in a direction parallel to a lengthwise direction of the channel region.

2. The semiconductor device as set forth in claim 1, wherein the first concentration is higher than the second concentration and the first region includes a boundary region between the channel region and the field isolation film.

3. The semiconductor device as set forth in claim 2, wherein the first region comprises two portions isolated from each other and the second region is disposed between the two portions.

4. The semiconductor device as set forth in claim 2, wherein the field isolation film adjacent to the first region includes the first impurity with the first concentration.

5. The semiconductor device as set forth in claim 1, wherein the source region and the drain region are doped with a second impurity, the first and second impurities having different electrical conductivity types.

6. The semiconductor device as set forth in claim 5, wherein the first impurity is at least one material selected from the group consisting of B, BF2, and In.

7. The semiconductor device as set forth in claim 1, wherein the gate electrode includes a charge storage film.

8. The semiconductor device as set forth in claim 1, wherein the gate electrode comprises:
a lower gate on a gate insulating layer;
an insulation film on the lower gate; and
an upper gate on the insulation film.

9. The semiconductor device as set forth in claim 1, which further comprises a floating diffusion region formed between the source region and the drain region,
wherein the gate electrode comprises a selection gate electrode and a memory gate electrode including the charge storage film, the selection gate electrode and the memory gate electrode being isolated from each other at both sides of the floating diffusion region.

10. The semiconductor device as set forth in claim 9, wherein the first and second regions are formed in the channel region under the selection gate electrode.

11. The semiconductor device as set forth in claim 9, wherein the first and second regions are formed in the channel region under the memory gate electrode.

12. The semiconductor device as set forth in claim 9, wherein the first concentration is from about 2.0×10¹⁴ to about 2.9×10¹⁴ ions/cm³.

13. The semiconductor device as set forth in claim 9, wherein the second concentration is from about 1.0×10¹⁴˜ to about 1.9×10¹⁴ ions/cm³.

14. A semiconductor device comprising:
a field isolation film defining an active region in a substrate;
a selection gate electrode extending crossing the active region and the field isolation film;
a memory gate electrode disposed in parallel with the selection gate electrode and including a floating gate;
a source region formed in the active region at a side of the memory gate electrode;
a drain region formed in the active region at a side of the selection gate electrode;
a floating diffusion region formed in the active region between the selection gate electrode and the memory gate electrode;
a first region doped with an impurity with a first concentration and a second region doped with the impurity with a second concentration different from the first concentration, formed in a channel region under the selection gate electrode and extending in a direction parallel to a lengthwise direction of the channel region; and
wherein the first concentration is higher than the second concentration and the first region includes a boundary region between the channel region and the field isolation film.

15. The semiconductor device as set forth in claim 14, further comprising a gate insulating film and a tunneling insulating film between the floating gate and the substrate.

16. The semiconductor device as set forth in claim 15, wherein the tunneling insulating film is thinner than the gate insulating film.

17. The semiconductor device as set forth in claim 15, wherein the tunneling insulating film is disposed on the floating diffusion region.

18. A method of fabricating a semiconductor device comprising:
forming a field isolation film defining an active region in a substrate;
implanting an impurity into the active region and forming a first region with a first concentration and a second region with a second concentration different from the first concentration which extend along a first direction;
forming a gate electrode extending along a second direction crossing the first direction and crossing the active region and the field isolation film, on the first and second regions; and
forming a source region and a drain region in the active region at both sides of the gate electrode.

19. The method as set forth in claim 18, wherein the first concentration is higher than the second concentration and the first region includes a boundary region between the channel region and the field isolation film.

20. The method as set forth in claim 19, wherein the first region comprises two portions isolated from each other, and the second region is disposed between the two portions.

21. The method as set forth in one of claim 19, wherein the first region is formed by implanting the impurity in a direction at an angle with respect to an imaginary line perpendicular to the first region, the angle being within a range of from about 7 to about 30 degrees.

22. The method as set forth in claim 20, wherein the first region is formed by implanting the impurity under a mask using a photoresist pattern that exposes an area including the boundary region.

23. The method as set forth in claim 22, which further comprises:
implanting an impurity into the substrate to form a well,
wherein the first region is formed within the well by implanting an additional impurity and the second region is formed between the two portions of the first regions.

24. The method as set forth in claim 22, which further comprises:
implanting an impurity into the substrate for controlling a threshold voltage,
wherein the first region is formed by implanting an additional impurity and the second region is formed between the two portions of the first region.

25. A method of fabricating a semiconductor device comprising:
forming a field isolation film defining an active region in a substrate;
forming a selection gate electrode on the active region and the field isolation film;
forming a memory gate electrode on the active region, the memory gate electrode being in parallel with the selection gate electrode and including a floating gate;
forming a source region in the active region at a side of the memory gate electrode;
forming a drain region in the active region at a side of the selection gate electrode;
forming a floating diffusion region in the active region between the selection gate electrode and the memory gate electrode;
forming a first region doped with an impurity with a first concentration and a second region doped with the impurity with a second concentration different from the first concentration, formed in a channel region under the selection gate electrode and extending in a direction parallel to a lengthwise direction of the channel region; and
wherein the first concentration is higher than the second concentration and the first region includes a boundary region between the channel region and the field isolation film.

26. The method as set forth in claim 25, further comprising forming a gate insulating film and a tunneling insulating film between the floating gate and the active region.

27. The method as set forth in claim 26, wherein the tunneling insulating film is thinner than the gate insulating film.

28. The method as set forth in claim 26, wherein the tunneling insulating film is formed on the floating diffusion region.
